(19) United States
(12) Patent Application Publication
(10) Pub. No.: US 2005/0219067 A1
(43) Pub. Date: Oct. 6, 2005

(54) Portable telephone keypad

(76) Inventor: Won Suk Chung, Chicago, IL (US)

Correspondence Address: Won Suk Chung, 1 W. Superior St. Apt.#4714, Chicago, IL, 60610, US

(21) Appl. No.: 11/097,765

(22) Filed: Apr. 2, 2005

Related U.S. Application Data
(60) Provisional application No. 60/559,368, filed on Apr. 2, 2004.

(51) Int. Cl. H03M 11/00; H03K 17/94

(52) U.S. Cl. 341/22; 379/433.06

(57) ABSTRACT

A keypad system operates in a first mode or a second mode. Each key cap is coupled to each group of adjacent two key switches. Each of first symbols is disposed on each of key caps. Two of each second symbols which is rotated 90 degrees to the first symbols are disposed over each key cap, and each of the two symbols is located over each of the key switches. When a key is actuated in the first mode, a first symbol assigned to the key cap is outputted. When a key is actuated in the second mode, a second symbol located over the actuated key switch is outputted. When there is a display operating with the keypad system, the contents of display can be oriented horizontal to the first symbols in the first mode or horizontal to the second symbol in the second mode.

### NONPROVISIONAL PATENT APPLICATION

This application claims the benefit of U.S. Provisional Patent Application No. 60/559,368 filed on Apr. 02, 2004.

### FIELD OF THE INVENTION

This invention is generally directed to a keyboard for a portable telephone or for a personal digital assistant (“PDA”). In particular, the invention relates to a keyboard adapted for sending text messages and for voice over data (“VOD”) applications. The keyboard can be adapted for use with a telephone, a cellular telephone, a PDA, a combination cellular telephone and PDA, or any other device in which both numeric entry and text entry is desired.

### BACKGROUND OF THE INVENTION

Telephones are commonly manufactured with a keypad style input system. The numbers one through nine appear starting in the upper left and proceeding left to right in a three-by-three array. The number zero is on the bottom row, with functional keys on the left (*) and right (#). The keys for numbers two through nine each correspond to three or four letters of the alphabet. This keypad arrangement, developed when dual-tone, multiple-frequency telephones replaced the rotary dial, has been kept for portable telephones, including cordless and cellular telephones. Cellular telephones, however, also commonly have additional keys above the numeric keypad, for such functions as “call” and “terminate call”, to increase or decrease volume, or redial.

A common cellular telephone keypad 100 as is presently known in the art is illustrated in FIG. 1. The keypad 100 of this telephone has five navigation keys 102, 104, 106, 108, and 110 arranged circumferentially around mouse key 112. In this keypad, various functions are assigned to the navigation keys: key 102 is redial, key 104 is talk, key 106 is send message, key 108 is terminate call, and key 110 is clear entry. Mouse key 112 is a quadruple rocker key with arrows and is used to navigate through menus on screen 114. Pressure on one of the four arrows of mouse key 112 moves the cursor on screen 114 in the direction of the arrow.

As the technology of cellular telephones developed, however, cellular telephones are now used not only for the traditional mode of voice transmission, but also for transmission of data. Text messaging, VOD, e-mail, internet pages, and graphics can all be transmitted to and from a cellular telephone. Accordingly, many cellular telephones, especially those with LCD screens, have arrow keys for navigation through various menu options displayed on the screen. Many users are accustomed to entering data and navigating menus through use of mice and computer keyboards, which have the QWERTY keyboard arrangement first developed for use in typewriters and kept for use in personal computers. FIG. 2 illustrates a QWERTY keyboard as is well known in the use of personal computers.

The numeric keypad, however, is not well adapted for entry of text. First of all, the standard keypad has only 12 keys, as shown in FIG. 1, which requires each numeric key to correspond to multiple letters (for example, the key for 7 corresponds to P, Q, R, and S). Although cellular telephones, as explained above, often have additional keys for other functions, these keys have not been used in the past to correspond to alphabetic characters. Accordingly, various systems have been developed to adapt the numeric keypad to the entry of text. One method is to press the number key multiple times to enter one of the letters corresponding to that key. For example, a user presses the number key “2” one time to enter the letter “A”, two times to enter the letter “B”, and three times to enter the letter “C”. This method is time consuming as well as difficult to use for users who are used to entering text on a personal computer using the traditional QWERTY keyboard.

Another method is to implement a traditional QWERTY keyboard on a cellular telephone. This method, however, increases the size of the telephone, whereas users prefer smaller units. Additionally, this method requires the choice of either implementing just a QWERTY keyboard, or implementing both the QWERTY keyboard and a numeric keypad. The first choice presents an obstacle for users who prefer to have the numeric keypad available for entering, for example, telephone numbers. The second choice makes the telephone even bulkier, contrary to the wishes of the marketplace.

Accordingly, a need exists for a cellular or other portable telephone that preserves the numeric keypad for entry of numbers, and has a QWERTY keyboard for entry of alphabetic text, and minimizes the size and weight of the device. The present invention meets this need.

### OBJECTS AND SUMMARY OF THE INVENTION

A general object of the present invention is to provide a keyboard for a cellular or portable telephone that can be adapted for use as a numeric keypad for entry of numbers and for use as a QWERTY keyboard for entry of text.

In furtherance of this object, the invention consists of a telephone having a keyboard and a screen, preferably an LCD screen, to display keyboard entries and other information. In the keyboard, number symbols and letter symbols are disposed on key caps, and the letter symbols are rotated approximately 90 degrees to the number symbols. For numeric entry and transmission of voice in telephone mode, the user set the telephone in number entry mode. Then the user, by applying pressure to each number key, enters numbers, and the inputted numbers are displayed in screen parallel to the number symbols in key caps.

The telephone is set in the letter entry mode by the user. The numeric keypad, in this second mode, having been rotated 90 degrees, operates as a QWERTY keyboard, with each number key corresponding to two adjacent letter keys. The user, by applying pressure on the right or left side of the key, enters one of the two letters, and the inputted letters are displayed in screen parallel to letter symbols in key caps. Thus, a user adept at text entry when using a QWERTY keyboard can enter text with very little additional training or effort, and also can easily reference the symbols without confusing between number and letter symbols.

This arrangement of a keypad allows the user of a telephone to use the device as a telephone and enter numbers as with existing telephones, yet also be able to enter text, for use in, for example, text messaging, game play, internet browsing, or e-mail, in an orientation and arrangement very nearly like a personal computer.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 is a plan view of a cellular telephone with keypad as known in the prior art.

FIG. 2 is a view of a computer keyboard as known in the prior art.

FIG. 3 shows a telephone in the closed position.

FIG. 4 is a perspective view of a telephone arranged in the preferred embodiment of the present invention, opened for use as a telephone.

FIG. 5 is a perspective view of a telephone arranged in the preferred embodiment of the present invention, opened for use in entering text.

FIGS. 6a through 6f show alternative embodiments of the keypad of the present invention.

FIG. 7a shows one embodiment of the dual-function key of the present invention.

FIG. 7b shows perspective view of FIG. 7a.

FIG. 7c shows the section view of FIG. 7a.

FIG. 7d shows how the keys of FIG. 7a fit onto a printed wiring board.

FIG. 7e shows another embodiment of the dual function key of the present invention.

FIG. 7f shows perspective view of FIG. 7e.

FIG. 7g shows the section view of FIG. 7e.

FIG. 7h shows how the keys of FIG. 7e fit onto a printed wiring board.

FIG. 8 is a block diagram of circuit 400 of one embodiment of the present invention.

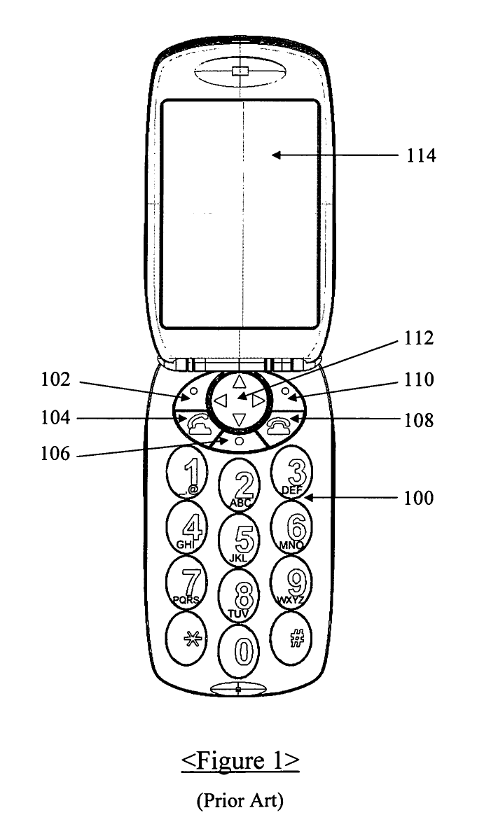

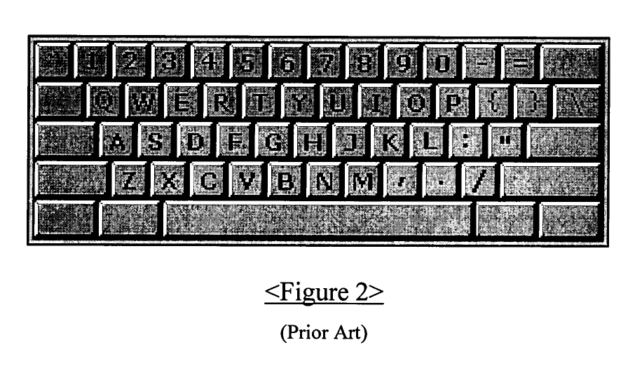

### DETAILED DESCRIPTION OF THE ILLUSTRATED EMBODIMENT

While the invention may be susceptible to embodiments in different forms, there is shown in the drawings, and herein will be described in detail, specific embodiments with the understanding that the present disclosure is to be considered an exemplification of the principles of the invention, and is not intended to limit the invention to that as illustrated and described herein.

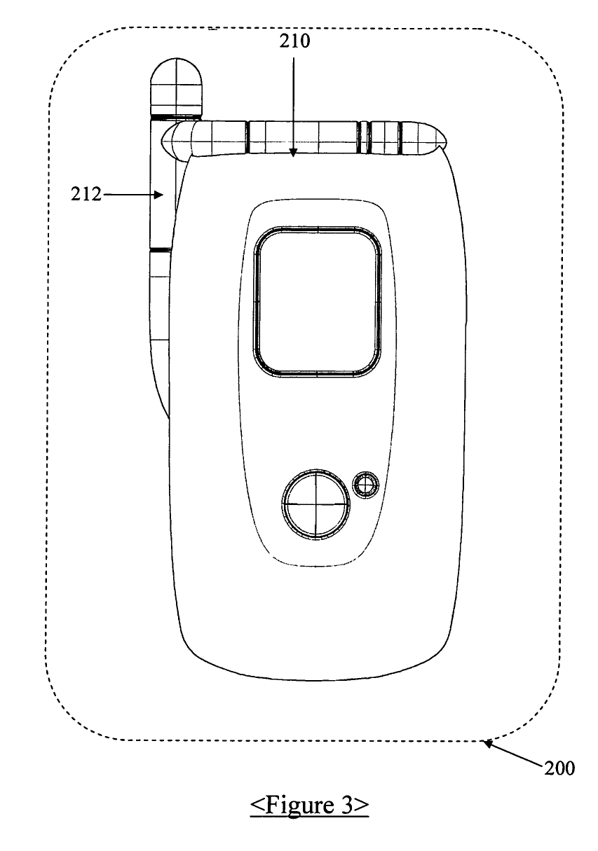

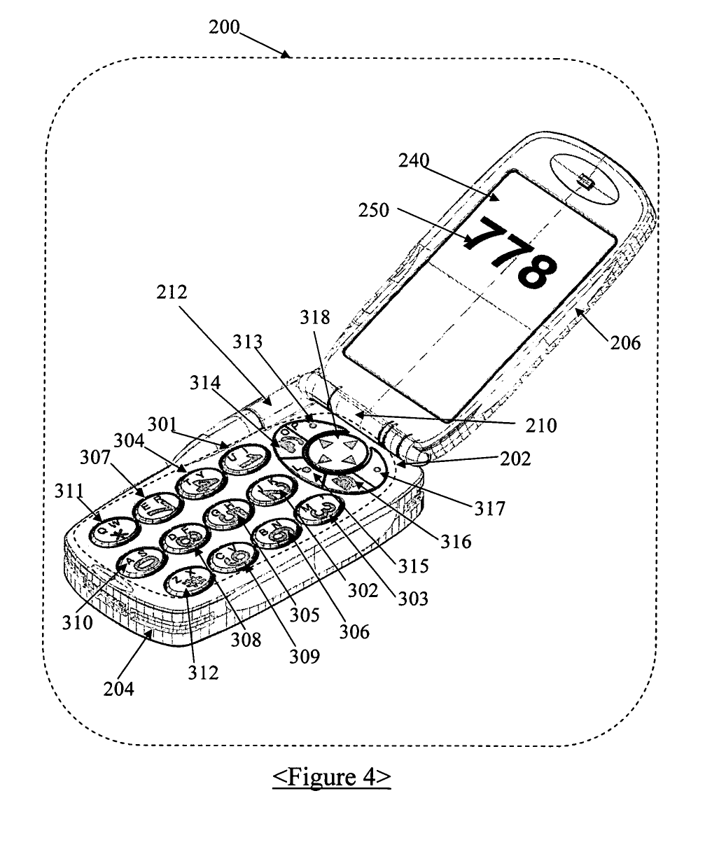

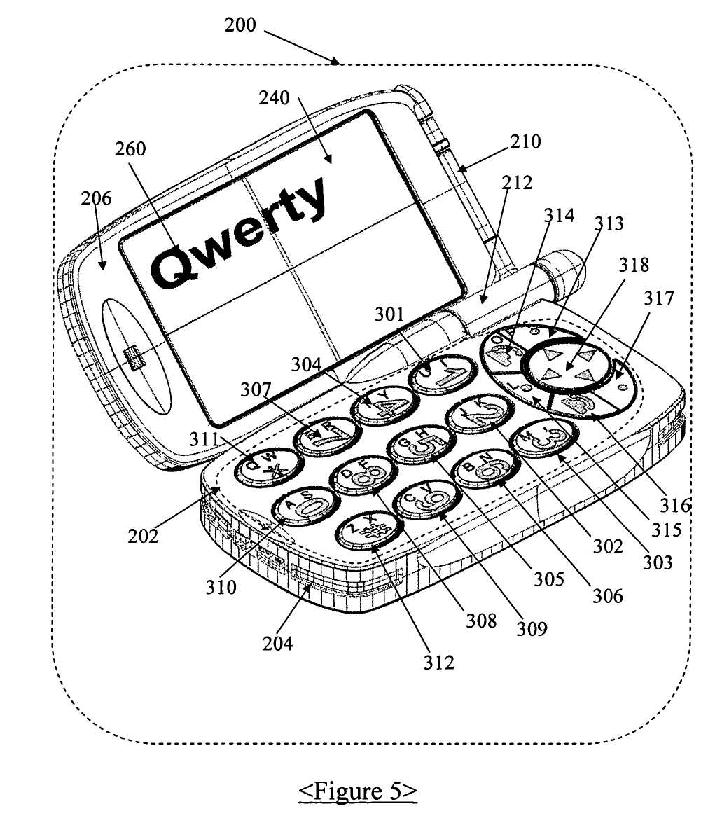

A telephone 200 of the present invention is shown in FIGS. 3, 4, and 5. The telephone 200 has two shells 204 and 206. Shells 204 and 206 articulate at first hinge 210 for use in numeric entry mode (or telephone mode), as illustrated in FIG. 4, and articulate at second hinge 212 for use in text entry mode, as illustrated in FIG. 5.

First shell 204 contains the keypad 202 for use in dialing telephone numbers or making numeric entries such as for accessing answering machines or navigating through voice mail. Keypad 202 has numeric keys in four rows of three keys:

| Element number | Key function |
|---|---|
| 301 | 1 |
| 302 | 2 |
| 303 | 3 |
| 304 | 4 |
| 305 | 5 |
| 306 | 6 |
| 307 | 7 |
| 308 | 8 |
| 309 | 9 |
| 310 | 0 |
| 311 | * |
| 312 | # |

Additionally, telephone 200 has navigation keys:

| Element number | Key function |
|---|---|
| 313 | Redial |
| 314 | Talk |
| 315 | send message |
| 316 | terminate call |
| 317 | clear entry |
| 318 | Mouse |

Please note that different telephones have different arrangements of navigation keys and keys 301 through 318 as illustrated in FIGS. 4 and 5 are examples and not a limitation.

Shell 204 connectrs to shell 206 at first hinge 210. Accordingly, shells 204 and 206 articulate about first hinge 210 from a closed position, as shown in FIG. 3, to an open position as shown in FIG. 4.

Shell 206 contains a screen 240, preferably an LCD screen, to display information relating to telephone calls. Information displayed includes, by way of example and not by way of information, numbers entered, incoming caller identification, stored entries, and call history. Screen 240 is preferably rectangular and appears to the use, in telephonic mode, in a portrait orientation.

Cellular telephone 200 is shown in plan view in FIG. 5 as configured for text entry. Shell 204 articulates with shell 206 at second hinge 212, from a closed position to an open position. In the open position, screen 240 appears in landscape mode.

The numeric keys 0 through 9, identified as keys 301 through 310, and the two function keys * and #, keys 311 and 312, are dual-function rocker keys. As is illustrated in FIG. 5, each key is assigned to two letters. For example, key 311, that appears on the lower left of the keypad 202 in telephonic mode, the * key, is assigned to the letters Q and W in the text entry mode and appears on the upper left of the keypad 202 in text entry mode. Because key 311 is a rocker key, pressure on key 311 causes it to depress to a first side 311a or to a second side 311b. In text entry mode, first 311a is to the left of the user and second side 311b is to the right side of the user. The user can depress key 311 to cause it to shift to the right or to the left. Accordingly, the user can touch the left side of key 311 to depress it to first side 311 a to enter Q and touch the right side of key 311 to depress it to second side 311b to enter W.

Thus, in text entry mode, the keys 301 through 312 have the following functions in the embodiment illustrated in FIG. 5:

| Element Number | Left Key Function | Right Key Function |
|---|---|---|
| 301 | U | I |
| 302 | J | K |
| 303 | M | , |
| 304 | T | Y |
| 305 | G | H |
| 306 | B | N |
| 307 | E | R |
| 308 | D | F |
| 309 | C | V |
| 310 | A | S |
| 311 | Q | W |
| 312 | Z | X |

This arrangement leaves several letters unassigned. Accordingly, some of the navigation keys are assigned to letters to complete the QWERTY keypad. These keys, however, are not dual function rocker keys, and accordingly do not rock to one side or another to enter different letters, as do the numeric keys described above. These keys are assigned as follows:

| Element Number | Key Function |
|---|---|
| 313 | P |
| 314 | O |
| 315 | L |
| 316 | send message |
| 317 | delete message |

As can be seen, then, the novel assignment of letters and the use of dual-function rocker keys allow the standard cellular telephone keypad to be used as a QWERTY keypad. This arrangement enables easy text entry with minimal training or practice to those already skilled in the use of a QWERTY keyboard.

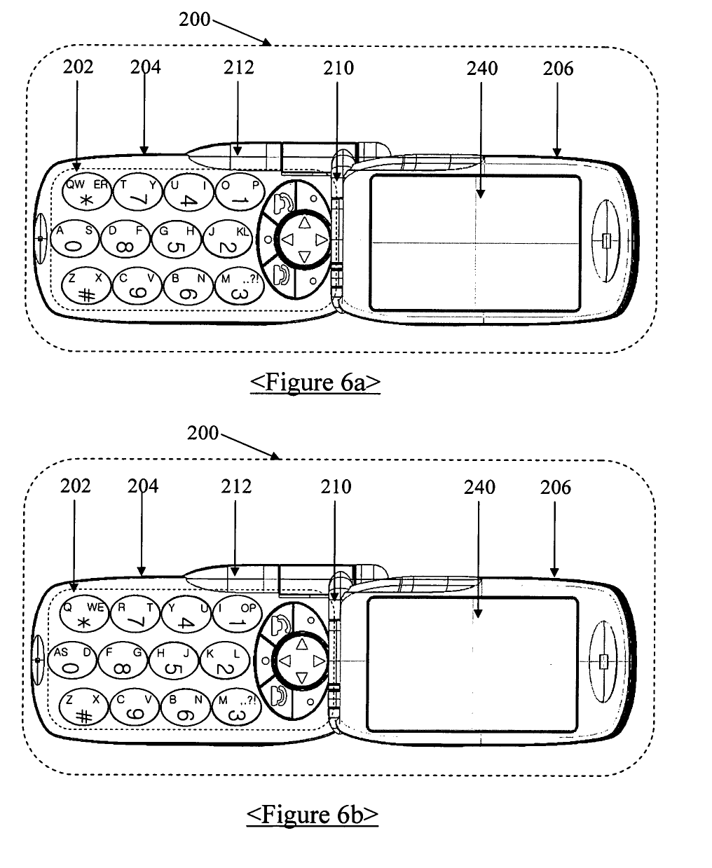

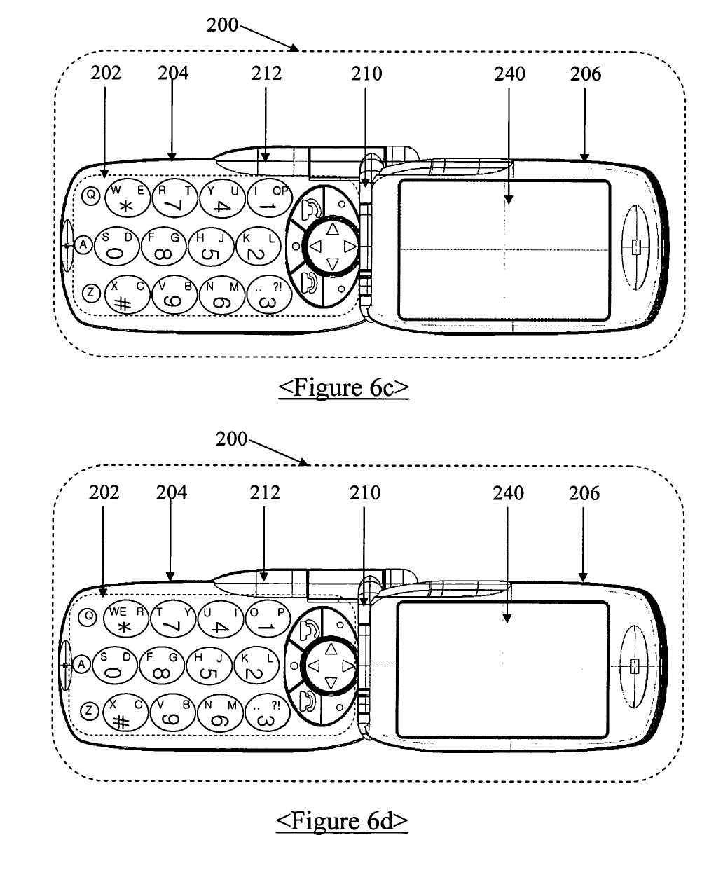

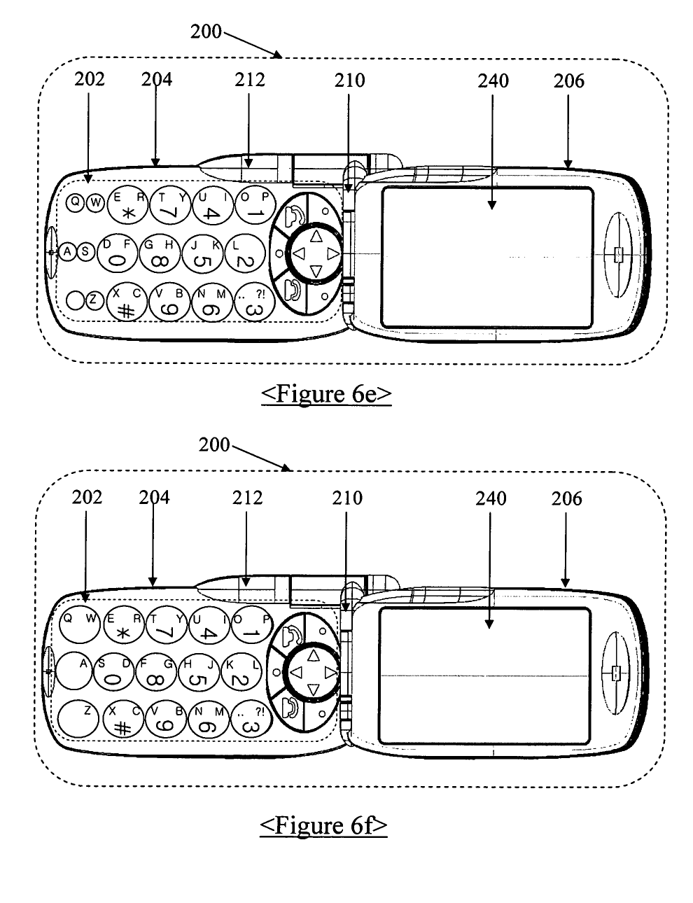

There are several alternative embodiments. In FIG. 6a, the function keys for the cellular telephone operation are not used for the QWERTY keypad. Instead, multiple letters are assigned to certain keys. Thus, the * key, which was assigned to the letters Q and W in the embodiment illustrated in FIG. 5, is assigned to the letters Q, W, E, and R in the embodiment illustrated in FIG. 6a. Pressure on the left side of the * key, pressed and released, enters the letter “Q”, while pressure on the left side of the * key, held for a count (or double clicking), enters the letter “W”. Similarly, pressure on the right side of the * key, pressed and released, enters the letter “E”, while pressure on the right side of the * key, held for a count, enters the letter “R”. Similarly, in this embodiment, the letters J, K, and L are assigned to the 2 key. Pressure of any nature on the left side of the 2 key, in text entry mode, enters the letter “J”. Pressure on the right side of the 2 key, pressed and released, enters the letter “K”, while pressure on the right side of the 2 key, held for a count (or double clicking), enters the letter “L”. Similarly, the letter M and multiple punctuation marks are assigned to the 3 key.

Similar arrangements are illustrated in FIG. 6b, wherein the letters Q, W, and E are assigned to the * key, the letters I, O, and P are assigned to the 1 key, the letters A, S, and D are assigned to the 0 key, and the letter M and multiple punctuation marks are assigned to the 3 key.

In FIGS. 6c and 6d, an extra row of keys is added to the bottom of the keypad and assigned to single letters. In these embodiments, several keys still have multiple letter assignments. For example, in FIG. 6c, the 1 key is assigned to the letters I, O, and P, in the manner described for FIG. 6b. In FIG. 6d, the * key is assigned to the letters W, E, and R, in the same manner.

In FIG. 6e, two extra rows of single-action keys are added to the bottom of the keypad. In FIG. 6f, only one extra row of keys is added, but these keys are dual function rocker keys. Thus, the newly added key in the top row is assigned to the letters Q and W. Pressure on the left side of the key enters the letter “Q” and pressure on the right side of the key enters the letter “W”.

In some of these embodiments, the navigation keys for the cellular telephone are not needed for the text-entry keyboard. Please note, however, that the keys in the additional row can be assigned other functions for text entry mode if desired, such as SHIFT, ENTER, SEND MESSAGE, or DELETE MESSAGE. Also, there are some unassigned keys in the embodiments illustrated. For example, in FIG. 6e, the extra key next to the Z key could be assigned to one of these other functions, such as SHIFT.

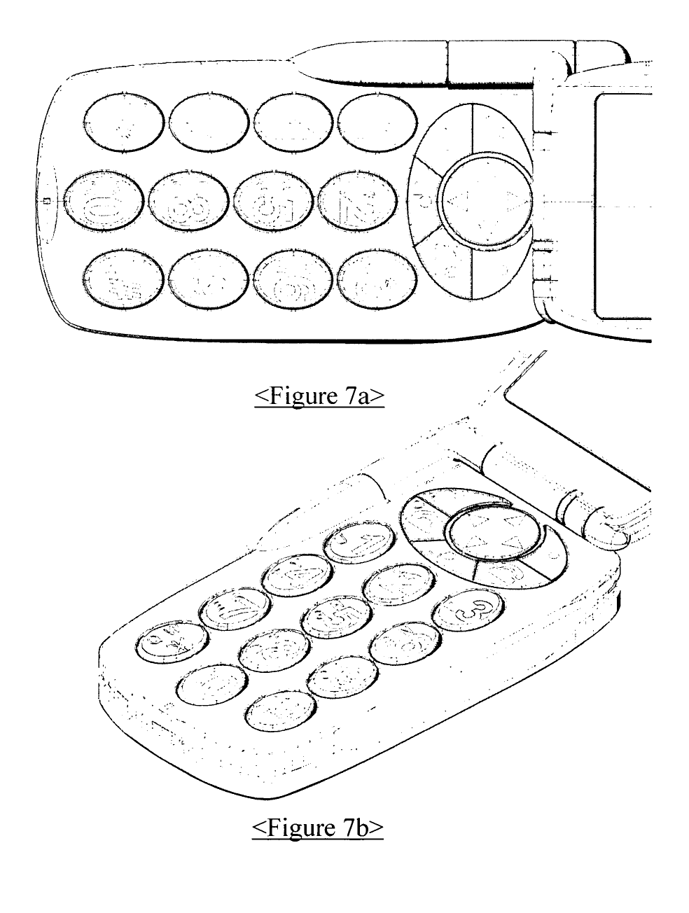

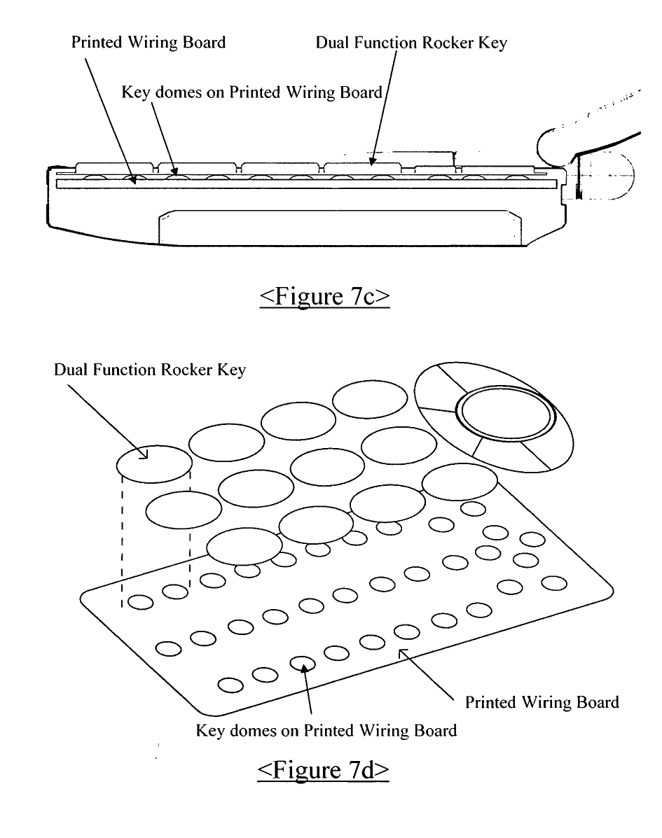

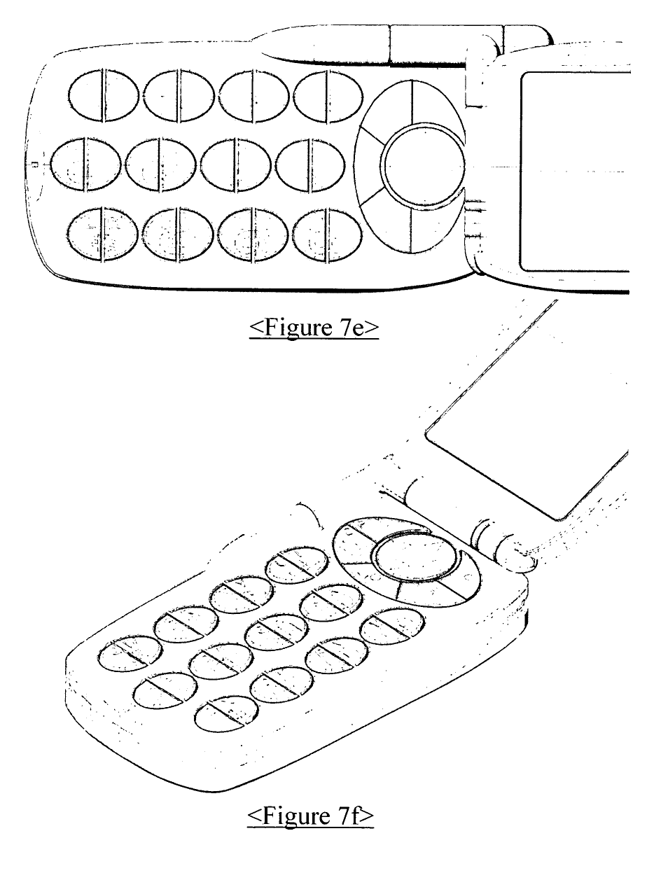

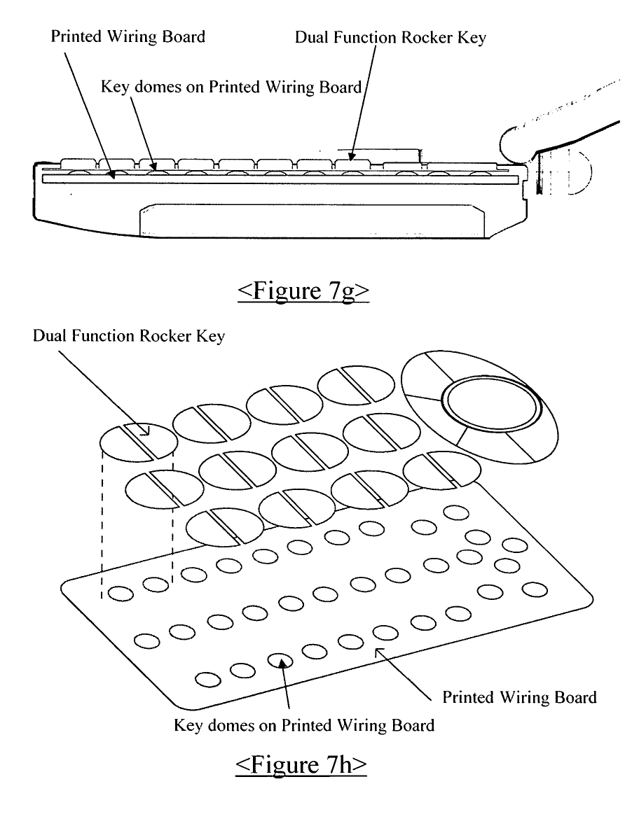

Two possible designs of the dual-function rocker keys, as described above, are illustrated in FIG. 7a and in FIG. 7e. FIG. 7a through 7d illustrate, in plan view, perspective view, in section view, and exploded view, one embodiment of the dual function rocker key. In this embodiment, depression of one side or another of the key, while in text entry mode, activates the function assigned to that particular side of that key. Thus, in the key illustrated in FIG. 7a, depressing the * key on the left side enters the letter “Q” and depressing the key on the right side enters the letter “W”. Please note that, in numeric entry mode, depression of the key anywhere enters a “*”.

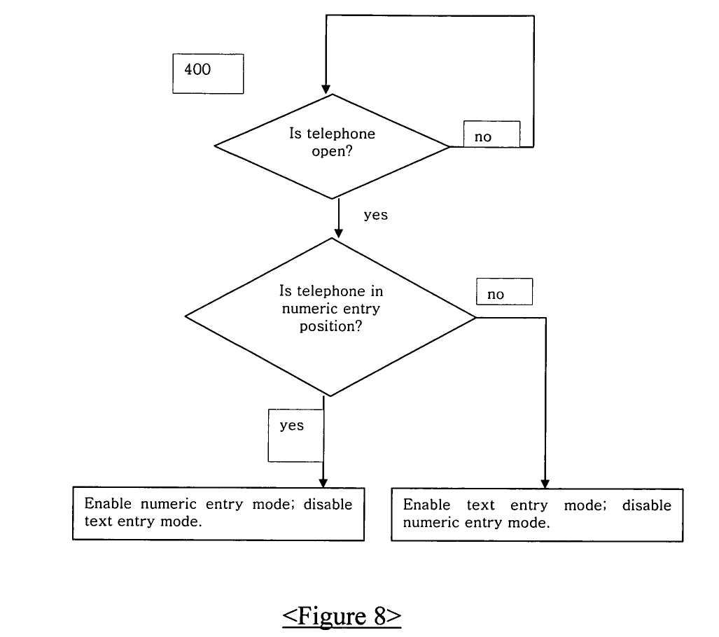

An alternative embodiment of the dual-function rocker key is illustrated in FIGS. 7e through 7h. In this embodiment, also illustrated in plan view, perspective view, section view, and exploded view, each key actually consists of two separate keys, aligned closely to each other. The keys are preferably of mirror-image shapes, preferably half-circles. In the illustrated embodiment, the two half-circular keys appear as an oval. Depression of the oval on the left side enters the letter “Q” and depression on the right side of the oval enters the letter “W” when in text entry mode. In numeric entry mode, depression anywhere on the oval enters a The keypad 202 preferably has a circuit 400 connected to first hinge 210 to detect in which mode the telephone 200 is being used, as illustrated in block diagram form in FIG. 8. Thus, when the user wishes to be in numeric entry mode, circuit 400 detects that the telephone 200 has been opened at first hinge 210 to the open position shown in FIG. 4. Circuit 400 therefore enables the dual-function keys to activate the numbers assigned to each key, and rotates the information 250 in the display parallel to the numbers assigned to each key. When the user wishes to enter text, circuit 400 detects that the telephone 200 has been opened at second hinge 212, to the open position shown in FIG. 5. Circuit 400 then enables each dual-function rocker key to activate one of the letters assigned to it, and rotates the information 260 in the display parallel to the letters assigned to each key. Alternatively, circuit 400 can be activated by a separate key on the keypad, either a dedicated key or one of the function keys. Thus, a user can, for example, press this dedicated key to toggle from text entry mode to numeric entry mode.

In an alternative embodiment, circuit 400 does not differentiate between numeric entry mode and text entry mode. Alternatively, the keys can be configured so that quick pressure and release on one key is, for example, text entry for that key, whereas pressure, held for a count, is numeric entry for that key. Alternatively, when the telephone is in the open position shown in FIG. 4, the input function is dedicated to numeric input; when user presses either the half-key (as in FIG. 7e) or either side of the key (as in FIG. 7a), the number is entered. When, however, the user keep holding or pressing the button, the number entered inputted on the screen will be changed to the alphabet character. If the user pressed a button that is assigned to two different alphabet characters, then the user will have choice of selection after keep holding or pressing the button. In the same way, when the shells are opened in an open position, the input function is dedicated to alphabetic input; when user presses the button, the alphabet character will be inputted, but when the user holds the button the number assigned to that button will be shown on display.

Please note that the illustrated examples of a QWERTY keyboard are just examples. The keypad 202 of the present invention could be adapted to the Dvorak keyboard without departing form the spirit of the present invention. Additionally, the keypad 202 could be adapted to a different alphabet, such as Han-gul, Cyrillic, Greek, or Chinese, without departing from the spirit of the present invention.

While preferred embodiments of the present invention are shown and described, it is envisioned that those skilled in the art may devise various modifications of the present invention.

1. A keypad system, comprising:
a circuit board;
a plurality of key switch means disposed on said circuit board;
a contact surface coupled to said plurality of key switch means;
a plurality of first symbols disposed upon said contact surface, wherein each of said first symbols is assigned to each group of said plurality of key switch means, each group comprising at least two adjacent ones of said plurality of key switch means.
a plurality of second symbols disposed upon said contact surface, wherein at least one of said second symbols (i) is assigned to each of key switch means, (ii) is located approximately above assigned key switch mean, and (iii) is approximately rotated 90 degrees to said plurality of first symbols;
a processor operating in a first mode or a second mode, wherein (i) when one of said plurality of key switch means in said group of plurality of key switch means is actuated in said first mode, said processor outputs a signal for a first symbol which is assigned to said group, (ii) when more than one of said plurality of key switch means in said group of plurality of key switch means are actuated simultaneously in said first mode, said processor outputs a signal for a first symbol which is assigned to said group, and (iii) when one of said plurality of key switch means is actuated in said second mode, said processor outputs a signal for a second symbol which is assigned to said actuated key switch mean; and
a switch mean for selecting mode between said first mode and said second mode.

2. A keypad system according to claim 1, wherein said switch mean for selecting mode comprises a key cap mean and a key switch mean disposed on said circuit board.

3. A keypad system according to claim 1, wherein said contact surface includes a plurality of key cap means, each of said plurality of key cap means coupled to each group of said plurality of key switch means wherein one key cap mean is shared as a contact surface for coupled group of said key switch means.

4. A keypad system according to claim 1, wherein said contact surface includes a plurality of key cap means, each of said plurality of key cap means coupled to each of said plurality of key switch means wherein key cap means in each group of said plurality of key switch means are aligned closely to each other, thereby forming a group of key cap means, and separating said group from other groups of key cap means.

5. A hand-held electronic apparatus, comprising:
an electronic device;
a screen; and
a keypad system connected to the electronic device for entering data into the electronic device, the keypad system comprising:
a circuit board;
a plurality of key switch means disposed on said circuit board;
a contact surface coupled to said plurality of key switch means;
a plurality of first symbols disposed upon said contact surface, wherein each of said first symbols is assigned to each group of said plurality of key switch means, each group comprising at least two adjacent ones of said plurality of key switch means.
a plurality of second symbols disposed upon said contact surface, wherein at least one of said second symbols (i) is assigned to each of key switch means, (ii) is located approximately above assigned key switch mean, and (iii) is approximately rotated 90 degrees to said plurality of first symbols;
a processor operating in a first mode or a second mode, wherein (i) when one of said plurality of key switch means in said group of plurality of key switch means is actuated in said first mode, said processor outputs a signal for a first symbol which is assigned to said group, (ii) when more than one of said plurality of key switch means in said group of plurality of key switch means are actuated simultaneously in said first mode, said processor outputs a signal for a first symbol which is assigned to said group, (iii) when one of said plurality of key switch means is actuated in said second mode, said processor outputs a signal for a second symbol which is assigned to said actuated key switch mean, (iv) said processor orients contents of said screen horizontal to said plurality of first symbols in said first mode, and (v) said processor orients contents of said screen horizontal to said plurality of second symbols in said second mode; and
a switch means for selecting mode between said first mode and said second mode.

6. A keypad system according to claim 5, wherein said switch means for selecting mode comprises a key cap mean and a key switch mean disposed on said circuit board.

7. A keypad system according to claim 5, wherein said switch mean for selecting mode comprises a hinge structure connecting said keypad part and said screen part wherein selection of mode between said first mode and said second mode depends on the rotated angle of said hinge structure.

8. A keypad system according to claim 5, wherein said contact surface includes a plurality of key cap means, each of said plurality of key cap means coupled to each group of said plurality of key switch means wherein one key cap mean is shared as a contact surface for coupled group of key switch means.

9. A keypad system according to claim 5, wherein said contact surface includes a plurality of key cap means, each of said plurality of key cap means coupled to each of said plurality of key switch means wherein key cap means in each group of said plurality of key switch means are aligned closely to each other, thereby forming a group of key cap means, and separating said group from other groups of key cap means.

10. A keypad system according to claim 5, wherein said plurality of first symbols comprises at least a numeric telephone-type set of symbols.

11. A keypad system according to claim 5, wherein said plurality of said second symbols comprises at least an alphabetic-type set of symbols.

12. A keypad system according to claim 11, wherein said alphabetic set of keys comprises a QWERTY keypad.
